(19) United States
(12) Patent Application Publication
(10) Pub. No.: US 2025/0271776 A1
(43) Pub. Date: Aug. 28, 2025

(54) IMAGE MODELING-ASSISTED METROLOGY

(71) Applicant: KLA Corporation, Milpitas, CA (US)

(72) Inventors: Stefan Eyring, Weilburg (DE); Detlef Michelsson, Löhnberg (DE); Mahrokh Javadi, Wetzlar (DE); Van-Thin Luu, Wetzlar (DE); Slawomir Czerkas, Weilburg (DE); Henning Stoschus, Wetzlar (DE); Frank Laske, Weilmünster (DE)

(21) Appl. No.: 19/051,118

(22) Filed: Feb. 11, 2025

Related U.S. Application Data
(60) Provisional application No. 63/556,399, filed on Feb. 22, 2024.

(51) Int. Cl. G03F 7/00

(52) U.S. Cl. CPC G03F 7/706831; G03F 7/70625; G03F 7/70655; G03F 7/706837; G03F 7/706841

(57) ABSTRACT

Methods and systems for determining characteristic(s) of patterned feature(s) on a specimen are provided. One system includes a computer subsystem configured for comparing one or more images of a specimen generated by an imaging subsystem with one or more modes, respectively, to rendered images generated for the one or more modes and at least one instance of a design for the specimen corresponding to at least one of different values of at least one characteristic of one or more patterned features in the design. The computer subsystem is also configured for determining one or more quality merits for results of the comparing and optimizing the one or more quality merits using an optimization method. In addition, the computer subsystem is configured for determining characteristic(s) of the patterned feature(s) on the specimen from results of the optimizing.

### BACKGROUND OF THE INVENTION

### 1. Field of the Invention

The present invention generally relates to methods and systems for image modeling-assisted metrology. Certain embodiments relate to determining one or more characteristics such as critical dimension (CD) of patterned features on a specimen by comparing image(s) of the specimen to rendered images generated for different combinations of imaging subsystem mode and patterned feature characteristic value(s) and optimizing quality merit(s) determined for the comparison results.

### 2. Description of the Related Art

The following description and examples are not admitted to be prior art by virtue of their inclusion in this section.

Fabricating semiconductor devices such as logic and memory devices typically includes processing a specimen such as a semiconductor wafer using a number of semiconductor fabrication processes to form various features and multiple levels of the semiconductor devices. For example, lithography is a semiconductor fabrication process that typically involves transferring a pattern to a resist arranged on a semiconductor wafer. Additional examples of semiconductor fabrication processes include, but are not limited to, chemical-mechanical polishing, etch, deposition, and ion implantation. Multiple semiconductor devices may be fabricated in an arrangement on a semiconductor wafer and then separated into individual semiconductor devices.

Metrology processes are used at various steps during a semiconductor manufacturing process to monitor and control the process. Metrology processes are different than inspection processes in that, unlike inspection processes in which defects are detected on a specimen, metrology processes are used to measure one or more characteristics of the specimen that cannot be determined using currently used inspection tools. For example, metrology processes are used to measure one or more characteristics of a specimen such as a dimension (e.g., line width, thickness, etc.) of features formed on the specimen during a process such that the performance of the process can be determined from the one or more characteristics. In addition, if the one or more characteristics of the specimen are unacceptable (e.g., out of a predetermined range for the characteristic(s)), the measurements of the one or more characteristics of the specimen may be used to alter one or more parameters of the process such that additional specimens manufactured by the process have acceptable characteristic(s).

Metrology processes are also different than defect review processes in that, unlike defect review processes in which defects that are detected by inspection are re-visited in defect review, metrology processes may be performed at locations at which no defect has been detected. In other words, unlike defect review, the locations at which a metrology process is performed on a specimen may be independent of the results of an inspection process performed on the specimen. In particular, the locations at which a metrology process is performed may be selected independently of inspection results. In addition, since locations on the specimen at which metrology is performed may be selected independently of inspection results, unlike defect review in which the locations on the specimen at which defect review is to be performed cannot be determined until the inspection results for the specimen are generated and available for use, the locations at which the metrology process is performed may be determined before an inspection process has been performed on the specimen.

There are many different types of metrology processes currently used in semiconductor manufacturing. Some currently used methods rely on relatively high resolution images (e.g., top layer images generated by a scanning electron microscope configured for measuring CD, i.e., a “CDSEM,” with a substantially small beam size). Some such methods determine the patterned feature characteristics directly from the images. For example, such metrology methods may apply a contour-detection or edge-detection algorithm (e.g., grayscale thresholding) to determine the size of the pattern. Different methods and tools may also be used depending on if the patterned feature characteristic being measured is at or below the upper surface of the specimen. For example, if a characteristic of a patterned feature on a buried layer is being measured, in currently used methods, the specimen is usually cut to generate slices. Those slices can then be measured in a “side-view” on tools such as transmission electron microscopes (TEMs) using image processing algorithms (e.g., grayscale thresholding).

There are a number of important disadvantages to the currently used metrology methods and systems. For example, the accuracy of the imaging method can be limited by the imaging conditions (e.g., beam size, pixel size, noise, etc.). In one such important example, edge blur caused by the limited resolution of the image (e.g., due to beam size/shape) directly impacts the CD value that can then be reported incorrectly. Another example of a disadvantage is that CD SEMs that are currently used for metrology tasks in the semiconductor industry need to use relatively low landing energies to achieve a substantially high resolution. Thus, such tools can only measure layers at or close to the surface. In addition, such CD SEMs need to use relatively low beam currents to achieve a substantially high resolution. Therefore, these tools are relatively slow. In the case of using a TEM for buried layer metrology, the patterns must be cut from the wafer prior to measuring the CD. As such, TEM is a destructive measurement and cannot be used as an in-line process control. In addition, cutting the substrate/pattern and measuring it on a TEM is substantially slow compared to other non-destructive in-line methods.

Accordingly, it would be advantageous to develop systems and methods for determining characteristic(s) of patterned feature(s) on a specimen that do not have one or more of the disadvantages described above.

### SUMMARY OF THE INVENTION

The following description of various embodiments is not to be construed in any way as limiting the subject matter of the appended claims.

One embodiment relates to a system configured for determining one or more characteristics of one or more patterned features on a specimen. The system includes an imaging subsystem configured for generating one or more images of a specimen with one or more modes of the imaging subsystem, respectively. The system also includes a computer subsystem configured for comparing the one or more images of the specimen generated by the imaging subsystem to rendered images generated for the one or more modes and at least one instance of a design for the specimen corresponding to at least one of different values of at least one characteristic of one or more patterned features in the design. The computer subsystem is also configured for determining one or more quality merits for results of the comparing and optimizing the one or more quality merits using an optimization method. In addition, the computer subsystem is configured for determining one or more characteristics of the one or more patterned features on the specimen from results of the optimizing. The system may be further configured as described herein.

Another embodiment relates to a computer-implemented method for determining one or more characteristics of one or more patterned features on a specimen. The method includes acquiring one or more images of a specimen generated with one or more modes of an imaging subsystem, respectively. The method also includes the comparing, determining one or more quality merits, optimizing, and determining one or more characteristics steps described above. The steps of the method are performed by a computer subsystem as described above. Each of the steps of the method may be performed as described further herein. The method may include any other step(s) of any other method(s) described herein. The method may be performed by any of the systems described herein.

An additional embodiment relates to a non-transitory computer-readable medium storing program instructions executable on a computer system for performing a computer-implemented method for determining one or more characteristics of one or more patterned features on a specimen. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Further advantages of the present invention will become apparent to those skilled in the art with the benefit of the following detailed description of the preferred embodiments and upon reference to the accompanying drawings in which:

FIGS. 1 and 2 are schematic diagrams illustrating side views of embodiments of a system configured as described herein;

FIG. 3 is a flow chart illustrating an embodiment of steps performed by a computer subsystem described herein for determining one or more characteristics of one or more patterned features on a specimen;

FIG. 4 is a schematic diagram illustrating a cross-sectional view of one example of a specimen and a characteristic of its patterned features below an upper surface of the specimen that may be determined according to embodiments described herein; and

FIG. 5 is a block diagram illustrating one embodiment of a non-transitory computer-readable medium storing program instructions for causing a computer system to perform a computer-implemented method described herein.

While the invention is susceptible to various modifications and alternative forms, specific embodiments thereof are shown by way of example in the drawings and are herein described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

The terms “design,” “design data,” and “design information” as used interchangeably herein generally refer to the physical design (layout) of an IC or other semiconductor device and data derived from the physical design through complex simulation or simple geometric and Boolean operations. The design may include any other design data or design data proxies described in commonly owned U.S. Pat. No. 7,570,796 issued on Aug. 4, 2009 to Zafar et al. and U.S. Pat. No. 7,676,077 issued on Mar. 9, 2010 to Kulkarni et al., both of which are incorporated by reference as if fully set forth herein. In addition, the design data can be standard cell library data, integrated layout data, design data for one or more layers, derivatives of the design data, and full or partial chip design data. Furthermore, the “design,” “design data,” and “design information” described herein refers to information and data that is generated by semiconductor device designers in a design process and is therefore available for use well in advance of printing of the design on any physical specimens such as reticles and wafers.

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

One embodiment relates to a system configured for determining one or more characteristics of one or more patterned features on a specimen. Some embodiments described herein are configured for image modeling-assisted metrology for patterned feature characteristics such as critical dimension (CD). The embodiments described herein advantageously provide substantially accurate extraction of CD (pattern size) of a pattern on a substrate (e.g., wafer or photomask) from an image (e.g., generated using a scanning electron microscope (SEM)). The embodiments advantageously are capable of using images acquired with a relatively low resolution (e.g., larger beam size or through-stack imaging of a buried layer) compared to currently used methods. Accuracy of the embodiments is at least partly achieved by using an image model (e.g., similar in configuration to image models that may be used for a type of inspection called die-to-database or “D:DB”) to take the imaging conditions into account.

In one embodiment, the specimen is a wafer. The wafer may include any wafer known in the semiconductor arts. Although some embodiments may be described herein with respect to a wafer or wafers, the embodiments are not limited in the specimen for which they can be used. For example, the embodiments described herein may be used for specimens such as reticles, flat panels, printed circuit boards, and other semiconductor specimens.

The term “patterned features” is used interchangeably herein with the terms “specimen structures” and “specimen features.” In general, the term “patterned features” is defined herein as features in a design for a specimen that are formed on the specimen in a fabrication process. The term “patterned features” is also used herein to refer to the design features that are patterned on the specimen as opposed to unpatterned layers included in some designs. The “patterned features” described herein are therefore commonly formed on specimens such as those described herein in processes like lithography and/or etch. In addition, while some defects or foreign material (like particles, fall-on materials, and residual materials) may be considered structures on a specimen in some instances, these are not considered patterned features in the embodiments described herein. Instead, the term “patterned features” as used herein refers to only the structures intentionally formed on the specimen in one or more steps of a fabrication process.

One embodiment of such a system includes an imaging subsystem configured for generating one or more images of a specimen with one or more modes of the imaging subsystem, respectively. In general, the imaging subsystem includes at least an energy source and a detector. The energy source is configured to generate energy that is directed to a specimen. The detector is configured to detect energy from the specimen and to generate output responsive to the detected energy.

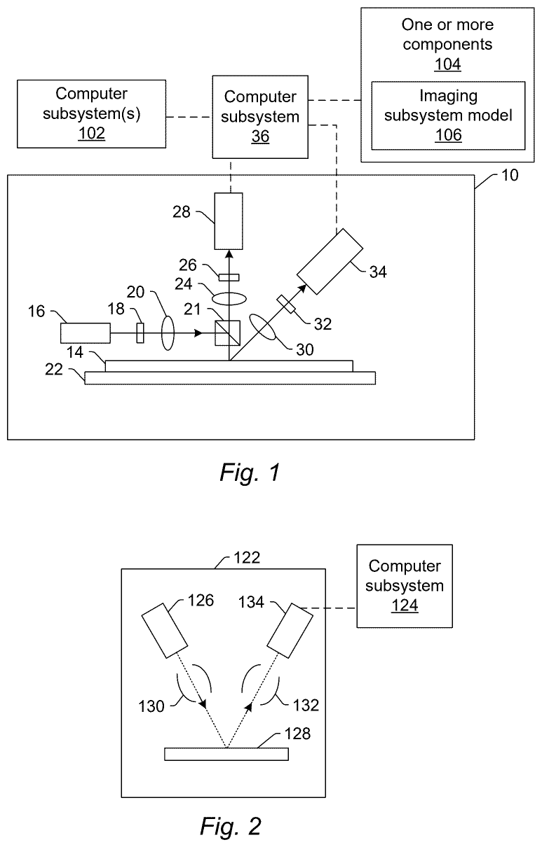

In one embodiment, the imaging subsystem is a light-based imaging subsystem. For example, in the embodiment of the system shown in FIG. 1, imaging subsystem 10 includes an illumination subsystem configured to direct light to specimen 14. The illumination subsystem includes at least one light source, e.g., light source 16. The illumination subsystem is configured to direct the light to the specimen at one or more angles of incidence, which may include one or more oblique angles and/or one or more normal angles. As shown in FIG. 1, light from light source 16 is directed through optical element 18 and then lens 20 to beam splitter 21, which directs the light to specimen 14 at a normal angle of incidence. The angle of incidence may include any suitable angle of incidence, which may vary depending on, for instance, characteristics of the specimen and the patterned features to be measured on the specimen.

The illumination subsystem may be configured to direct the light to the specimen at different angles of incidence at different times. For example, the imaging subsystem may be configured to alter one or more characteristics of one or more elements of the illumination subsystem such that the light can be directed to the specimen at an angle of incidence that is different than that shown in FIG. 1. In one such example, the imaging subsystem may be configured to move light source 16, optical element 18, and lens 20 such that the light is directed to the specimen at a different angle of incidence.

In some instances, the imaging subsystem may be configured to direct light to the specimen at more than one angle of incidence at the same time. For example, the imaging subsystem may include more than one illumination channel, one of the illumination channels may include light source 16, optical element 18, and lens 20 as shown in FIG. 1 and another of the illumination channels (not shown) may include similar elements, which may be configured differently or the same, or may include at least a light source and possibly one or more other components such as those described further herein. If such light is directed to the specimen at the same time as the other light, one or more characteristics (e.g., wavelength, polarization, etc.) of the light directed to the specimen at different angles of incidence may be different such that light resulting from illumination of the specimen at the different angles of incidence can be discriminated from each other at the detector(s).

In another instance, the illumination subsystem may include only one light source (e.g., source 16 shown in FIG. 1) and light from the light source may be separated into different optical paths (e.g., based on wavelength, polarization, etc.) by one or more optical elements (not shown) of the illumination subsystem. Light in each of the different optical paths may then be directed to the specimen. Multiple illumination channels may be configured to direct light to the specimen at the same time or at different times (e.g., when different illumination channels are used to sequentially illuminate the specimen). In another instance, the same illumination channel may be configured to direct light to the specimen with different characteristics at different times. For example, in some instances, optical element 18 may be configured as a spectral filter and the properties of the spectral filter can be changed in a variety of different ways (e.g., by swapping out the spectral filter) such that different wavelengths of light can be directed to the specimen at different times. The illumination subsystem may have any other suitable configuration known in the art for directing light having different or the same characteristics to the specimen at different or the same angles of incidence sequentially or simultaneously.

In one embodiment, light source 16 includes a broadband plasma (BBP) light source. In this manner, the light generated by the light source and directed to the specimen may include broadband light. However, the light source may include any other suitable light source such as a laser, which may be any suitable laser known in the art configured to generate light at any suitable wavelength(s) known in the art. The laser may be configured to generate light that is monochromatic or nearly-monochromatic. In this manner, the laser may be a narrowband laser. The light source may also include a polychromatic light source that generates light at multiple discrete wavelengths or wavebands.

Light from optical element 18 may be focused to beam splitter 21 by lens 20. Although lens 20 is shown in FIG. 1 as a single refractive optical element, in practice, lens 20 may include a number of refractive and/or reflective optical elements that in combination focus the light from the optical element to the specimen. The illumination subsystem shown in FIG. 1 and described herein may include any other suitable optical elements (not shown). Examples of such optical elements include, but are not limited to, polarizing component(s), spectral filter(s), spatial filter(s), reflective optical element(s), apodizer(s), beam splitter(s), aperture(s), and the like, which may include any such suitable optical elements known in the art. In addition, the system may be configured to alter one or more elements of the illumination subsystem based on the type of illumination to be used for imaging.

The imaging subsystem may also include a scanning subsystem configured to cause the light to be scanned over the specimen. For example, the imaging subsystem may include stage 22 on which specimen 14 is disposed during imaging. The scanning subsystem may include any suitable mechanical and/or robotic assembly (that includes stage 22) that can be configured to move the specimen such that the light can be scanned over the specimen. In addition, or alternatively, the imaging subsystem may be configured such that one or more optical elements of the imaging subsystem perform some scanning of the light over the specimen. The light may be scanned over the specimen in any suitable fashion.

The imaging subsystem further includes one or more detection channels. At least one of the one or more detection channels includes a detector configured to detect light from the specimen due to illumination of the specimen by the imaging subsystem and to generate output responsive to the detected light. For example, the imaging subsystem shown in FIG. 1 includes two detection channels, one formed by collector 24, element 26, and detector 28 and another formed by collector 30, element 32, and detector 34. As shown in FIG. 1, the two detection channels are configured to collect and detect light at different angles of collection. In some instances, one detection channel is configured to detect specularly reflected light, and the other detection channel is configured to detect light that is not specularly reflected (e.g., scattered, diffracted, etc.) from the specimen. However, two or more of the detection channels may be configured to detect the same type of light from the specimen (e.g., specularly reflected light). Although FIG. 1 shows an embodiment of the imaging subsystem that includes two detection channels, the imaging subsystem may include a different number of detection channels (e.g., only one detection channel or two or more detection channels). Although each of the collectors are shown in FIG. 1 as single refractive optical elements, each of the collectors may include one or more refractive optical element(s) and/or one or more reflective optical element(s).

The one or more detection channels may include any suitable detectors known in the art such as photo-multiplier tubes (PMTs), charge coupled devices (CCDs), and time delay integration (TDI) cameras. The detectors may also include non-imaging detectors or imaging detectors. If the detectors are non-imaging detectors, each of the detectors may be configured to detect certain characteristics of the scattered light such as intensity but may not be configured to detect such characteristics as a function of position within the imaging plane. As such, the output that is generated by each of the detectors included in each of the detection channels may be signals or data, but not image signals or image data. In such instances, a computer subsystem such as computer subsystem 36 may be configured to generate images of the specimen from the non-imaging output of the detectors. However, in other instances, the detectors may be configured as imaging detectors that are configured to generate imaging signals or image data. Therefore, the imaging subsystem may be configured to generate images in a number of ways.

Computer subsystem 36 of the system may be coupled to the detectors of the imaging subsystem in any suitable manner (e.g., via one or more transmission media, which may include “wired” and/or “wireless” transmission media) such that the computer subsystem can receive the output generated by the detectors during scanning of the specimen. Computer subsystem 36 may be configured to perform a number of functions using the output of the detectors as described herein and any other functions described further herein. This computer subsystem may be further configured as described herein.

This computer subsystem (as well as other computer subsystems described herein) may also be referred to herein as computer system(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer subsystem, the different computer subsystems may be coupled to each other such that images, data, information, instructions, etc. can be sent between the computer subsystems as described further herein. For example, computer subsystem 36 may be coupled to computer subsystem(s) 102 (as shown by the dashed line in FIG. 1) by any suitable transmission media, which may include any suitable wired and/or wireless transmission media known in the art. Two or more of such computer subsystems may also be effectively coupled by a shared computer-readable storage medium (not shown).

Although the imaging subsystem is described above as an optical or light-based subsystem, the imaging subsystem may be an electron-based subsystem. For example, in one embodiment, the energy directed to the specimen includes electrons, and the energy detected from the specimen includes electrons. In this manner, the energy source may be an electron beam source. In one such embodiment shown in FIG. 2, the imaging subsystem includes electron column 122, which is coupled to computer subsystem 124.

As also shown in FIG. 2, the electron column includes electron beam source 126 configured to generate electrons that are focused to specimen 128 by one or more elements 130. The electron beam source may include, for example, a cathode source or emitter tip, and one or more elements 130 may include, for example, a gun lens, an anode, a beam limiting aperture, a gate valve, a beam current selection aperture, an objective lens, and a scanning subsystem, all of which may include any such suitable elements known in the art.

Electrons returned from the specimen (e.g., secondary electrons) may be focused by one or more elements 132 to detector 134. One or more elements 132 may include, for example, a scanning subsystem, which may be the same scanning subsystem included in element(s) 130.

The electron column may include any other suitable elements known in the art. In addition, the electron column may be further configured as described in U.S. Pat. No. 8,664,594 issued Apr. 4, 2014 to Jiang et al., U.S. Pat. No. 8,692,204 issued Apr. 8, 2014 to Kojima et al., U.S. Pat. No. 8,698,093 issued Apr. 15, 2014 to Gubbens et al., and U.S. Pat. No. 8,716,662 issued May 6, 2014 to MacDonald et al., which are incorporated by reference as if fully set forth herein.

Although the electron column is shown in FIG. 2 as being configured such that the electrons are directed to the specimen at an oblique angle of incidence and are scattered from the specimen at another oblique angle, the electron beam may be directed to and scattered from the specimen at any suitable angles. In addition, the electron beam subsystem may be configured to use multiple modes to generate images of the specimen (e.g., with different illumination angles, collection angles, etc.), which may be different in any image generation parameter(s) of the subsystem.

Computer subsystem 124 may be coupled to detector 134 as described above. The detector may detect electrons returned from the surface of the specimen thereby forming electron beam images of the specimen. The electron beam images may include any suitable electron beam images. Computer subsystem 124 may be configured to perform any of the functions described herein using the output of the detector and/or the electron beam images. Computer subsystem 124 may be configured to perform any additional step(s) described herein. A system that includes the imaging subsystem shown in FIG. 2 may be further configured as described herein.

FIGS. 1 and 2 are provided herein to generally illustrate configurations of an imaging subsystem that may be included in the system embodiments described herein. Obviously, the imaging subsystem configuration described herein may be altered to optimize the performance of the system as is normally performed when designing a commercial imaging system. In addition, the systems described herein may be implemented using an existing imaging system (e.g., by adding functionality described herein to an existing metrology system) such as the metrology tools that are commercially available from KLA Corp., Milpitas, Calif. For some such systems, the embodiments described herein may be provided as optional functionality of the imaging system (e.g., in addition to other functionality of the imaging system). Alternatively, the imaging subsystem described herein may be designed “from scratch” to provide a completely new imaging system.

Although the imaging subsystem is described above as being a light- or electron beam-based subsystem, the imaging subsystem may be an ion beam-based subsystem. Such an imaging subsystem may be configured as shown in FIG. 2 except that the electron beam source may be replaced with any suitable ion beam source known in the art. Therefore, the energy directed to the specimen may include ions. In addition, the imaging subsystem may be any other suitable ion beam-based imaging subsystem such as those included in commercially available focused ion beam (FIB) systems, helium ion microscopy (HIM) systems, and secondary ion mass spectroscopy (SIMS) systems.

The imaging subsystems described herein may be configured to generate output, e.g., images, of the specimen with multiple modes (also referred to herein as “imaging conditions” and “imaging properties”). In general, a “mode” is defined by the values of parameters of the imaging subsystem used for generating output and/or images of a specimen (or the output used to generate images of the specimen). Therefore, modes may be different in the values for at least one of the parameters of the imaging subsystem (other than position on the specimen at which the output is generated). For example, in an optical subsystem, different modes may use different wavelength(s) of light for illumination. The modes may be different in the illumination wavelength(s) as described further herein (e.g., by using different light sources, different spectral filters, etc. for different modes). In another example, different modes may use different illumination channels of the optical subsystem. For example, as noted above, the optical subsystem may include more than one illumination channel. As such, different illumination channels may be used for different modes. The modes may also or alternatively be different in one or more collection/detection parameters of the optical subsystem. The modes may be different in any one or more alterable parameters (e.g., illumination polarization(s), angle(s), wavelength(s), etc., detection polarization(s), angle(s), wavelength(s), etc.) of the imaging subsystem. The imaging subsystem may be configured to scan the specimen with the different modes in the same scan or different scans, e.g., depending on the capability of using multiple modes to scan the specimen at the same time.

In a similar manner, the electron beam subsystem may generate images with one or more different values of a parameter of the electron beam subsystem. The multiple modes of the electron beam subsystem can be defined by the values of parameters of the electron beam subsystem used for generating images for a specimen. Therefore, modes may be different in the values for at least one of the electron beam parameters of the electron beam subsystem. For example, different modes may use different angles of incidence for illumination.

As noted above, the imaging subsystem may be configured for scanning energy (e.g., light, electrons, etc.) over a physical version of the specimen thereby generating images for the physical version of the specimen. In this manner, the imaging subsystem may be configured as an “actual” subsystem, rather than a “virtual” subsystem. However, a storage medium (not shown) and computer subsystem(s) 102 shown in FIG. 1 may be configured as a “virtual” system. In particular, the storage medium and the computer subsystem(s) may be configured as a “virtual” metrology system as described in commonly assigned U.S. Pat. No. 8,126,255 issued on Feb. 28, 2012 to Bhaskar et al. and U.S. Pat. No. 9,222,895 issued on Dec. 29, 2015 to Duffy et al., both of which are incorporated by reference as if fully set forth herein. The embodiments described herein may be further configured as described in these patents.

The computer subsystem is configured for acquiring the one or more images of the specimen generated by the imaging subsystem. Acquiring the one or more images of the specimen may include simply generating image(s) of the specimen using an imaging subsystem described herein. For example, the computer subsystem may acquire the one or more images of the specimen (also referred to herein as “measured image(s)”) (containing process variation, noise, etc.) at one or multiple imaging conditions (e.g., multiple landing energies). Acquiring the one or more images of the specimen may, however, be performed without the imaging subsystem. For example, the one or more images of the specimen may be acquired from a storage medium (such as one of those described further herein) in which the image(s) have been stored by another system or method.

In any of such cases, the one or more images of the specimen may include simply image(s) of the specimen generated by detector(s) of the imaging subsystem. Acquiring the one or more images of the specimen may, however, include performing any suitable image processing known in the art on the image(s) generated by detector(s) of the imaging subsystem. In this manner, the one or more images of the specimen may simply be the raw images generated by the imaging subsystem or may have been processed in some manner (e.g., to reduce noise in the images). The image processing may include any image processing normally used in metrology processes although such image processing may be advantageously unnecessary for the embodiments described herein since the metrology information is not determined directly from the measured images.

In one embodiment, the computer subsystem is configured for identifying responsivities of the modes of the imaging subsystem to the one or more characteristics and selecting at least two of the modes included in the one or more modes having different identified responsivities. For example, nearly identical pattern signals can sometimes only be separated by taking different imaging properties of the imaging conditions into account. In other words, sometimes, multiple modes may be needed to accurately determine patterned feature characteristic(s). In one such example, sometimes, even the best imaging subsystem mode may only produce images that are minimally different for different patterned feature characteristic values. In any of such situations, multiple modes may be used to provide more measured images and thereby more ways to determine the patterned feature characteristic(s).

When the images are generated with multiple modes, the multiple modes may be selected by another method or system (as would be normally done in recipe setup) and then information for the multiple modes may be acquired by the computer subsystem and used for the steps described herein. However, the computer subsystem may be configured to select the modes that are used in the embodiments described herein. For example, the computer subsystem may be configured to render images as described herein for some or even all of the imaging modes that are available on the imaging subsystem. For each of the modes being considered, the computer subsystem may render images for at least one of different values of the patterned feature characteristic of interest.

The images rendered for a single mode may then be examined to determine if they can be used to determine the patterned feature characteristic value. In the case that a single mode is not found to be responsive to a suitable range of patterned feature characteristic values, the rendered images generated for different combinations of modes may be evaluated to determine if they can be used in combination to determine the patterned feature characteristic values. The best possible mode or mode combination may then be selected and used for measuring and rendering images as described herein. This process may be repeated for as many patterned feature characteristics that are of interest, and the computer subsystem may try to find the fewest number of modes that are responsive to all of the patterned feature characteristics of interest. In this manner, the computer subsystem described herein may perform at least a portion of the metrology process recipe setup.

In another embodiment, the computer subsystem is configured for identifying responsivities of the modes of the imaging subsystem to different layers formed on the specimen and selecting at least two modes included in the one or more modes having different identified responsivities. The different layers may include, for example, an uppermost layer formed on the specimen and one or more buried layers formed under the uppermost layer. Different patterned features may be formed on the different layers, e.g., a contact hole on one layer and a trench on a different layer. The different layers may also be different locations along the height of the patterned features, e.g., like top and bottom CDs as described further herein.

In any of such cases, in the same manner described above, the computer subsystem may evaluate different modes to determine which of the modes are responsive to patterned feature characteristic(s) on different layers formed on the specimen. In addition, the computer subsystem may evaluate imaging subsystem parameters such as landing energy and beam current in the case of electron systems to find parameters that are differently responsive to patterned features and/or patterned feature characteristics formed on different layers of the specimen. For example, the computer subsystem may render images for different imaging parameters and at least one of different values of patterned feature characteristics on different layers of the specimen. The computer subsystem may then analyze those rendered images to try to find two or more modes that are differently responsive to only the patterned feature characteristic(s) of interest on different layers of interest. In one such example, a first mode may be responsive to a patterned feature characteristic of interest on a first layer, and a second mode may be responsive to a patterned feature characteristic of interest on a second layer. Both of such modes may be identified and selected by the computer subsystem for use in the embodiments. In any of such cases, the computer subsystem may perform steps described herein to determine if the images rendered for different modes can be used to accurately determine the patterned feature characteristic(s) of interest on the layer(s) of interest.

In an additional embodiment, the system includes one or more components (e.g., one or more components 104 shown in FIG. 1) executable by the computer subsystem (e.g., computer subsystem 36), the one or more components include a model of the imaging subsystem (e.g., imaging subsystem model 106), and the computer subsystem is configured for generating the rendered images by inputting into the model information for the mode(s) and at least one instance of a design for the specimen corresponding to at least one value of at least one characteristic of patterned feature(s) in the design. The computer subsystem may be configured to input the information for the mode(s) and the at least one instance of the design in any suitable manner known in the art. In this manner, the computer subsystem may generate a set of simulated images for various combinations of patterned feature characteristics and imaging modes. In other words, the computer subsystem may generate rendered images for one or more different patterned feature characteristic(s) and image mode 1, rendered images for the one or more different patterned feature characteristic(s) and image mode 2, and so on.

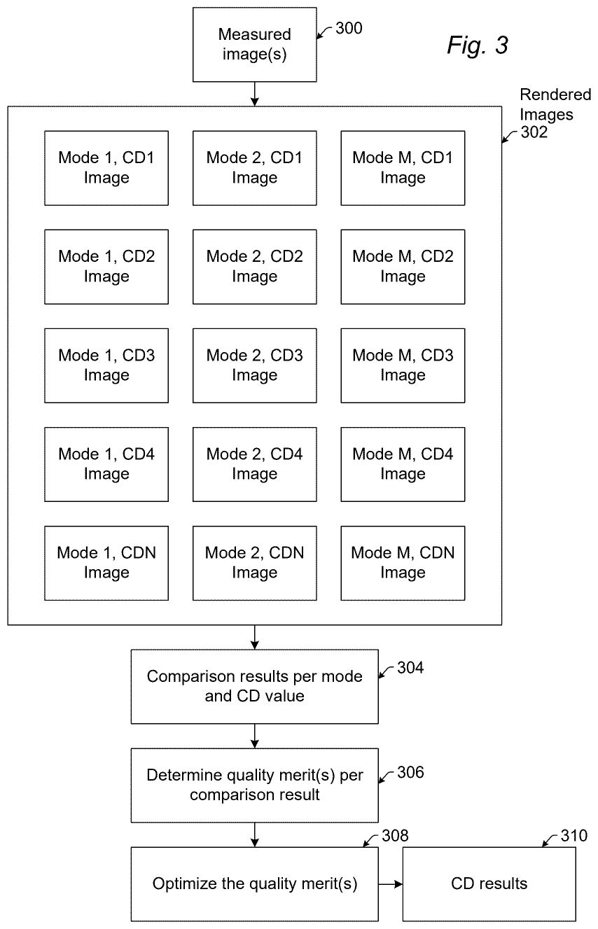

To illustrate this schematically as shown in FIG. 3, rendered images 302 for M different modes and N different CD values are shown. In particular, rendered images 302 for a first mode and N different CD values (CD1, CD2, . . . CDN) include Mode 1, CD1 image, Mode 1, CD2 image, . . . Mode 1, CDN image. Rendered images for another mode and the same N different CD values include Mode 2, CD1 image, Mode 2, CD2 image, . . . Mode N, CDN image. Similarly, rendered images for mode M and the same N different CD values include Mode M, CD1 image, Mode M, CD2 image, . . . Mode M, CDN image. Although images are shown in FIG. 3 as being rendered for 3 different modes and 5 different CD values, the embodiments may be configured for generating as many different rendered images as selected, suitable, and/or practical. In addition, although each of the rendered images are shown in FIG. 3 as being generated for CD, the rendered images may be generated for one or more different patterned feature characteristics (e.g., images for each of the modes as a function of different combinations of at least one value of a top CD and a bottom CD of the patterned features).

Each of the modes for which images are rendered may be a single mode of the imaging subsystem. Single mode, rendered images may be suitable for single mode metrology processes. In situations in which multiple modes are used in a metrology process, the multiple modes may be accounted for in the rendered images in a couple of different ways. In particular, for any one mode, the rendered image for one patterned feature characteristic value preferably looks as similar as possible to the measured image for a specimen on which the patterned feature having that characteristic value is formed. Therefore, if a measured image that would normally be used for metrology is an image generated from multiple mode images measured for the specimen, then the rendered images are preferably generated in the same way. In other words, rendered images are preferably generated for each of the multiple modes and then combined in the same way that the measured images normally would be.

In another example, if the measured images are processed in some manner for the purpose of metrology, the rendered images may be processed in the same manner prior to use in other steps described herein. Such image processing of the rendered images may, however, be unnecessary for several reasons, e.g., the rendered images will not be subject to possible noise sources on the specimen since they are being rendered from design information for the specimen. In such cases, the rendered image may be a simulated detector image, and its corresponding measured image may be a measured detector image subsequent to any image processing normally performed during the metrology process. In an alternative, the rendered and measured images may be rendered and measured raw detector images, respectively, i.e., images as they would be generated by a detector of the imaging subsystem without any other image processing.

In this manner, the embodiments described herein combine CD extraction with a die-to-database (D:DB) type modeling of the imaging conditions to perform an optimization. The imaging subsystem model may include any suitable such model known in the art. In other words, the embodiments described herein are advantageously not specific to any one imaging subsystem model or type of model. Some examples of suitable models of the imaging subsystem that may be used in the embodiments described herein include, but are not limited to, physical models, Monte-Carlo simulation-based modeling, and machine learning (ML)-based models (e.g., a generative adversarial network (GAN), a generative neural network (GNN), etc.).

The computer subsystem may calibrate the imaging model for one or multiple imaging conditions (e.g., multiple landing energies) in any suitable manner known in the art. In addition, any system or method may calibrate the imaging model in any suitable manner, which may then be used by the computer subsystem to generate the rendered images as described herein. In other words, one system may calibrate the imaging model, and another system may use the imaging model.

The input to the rendering step may, therefore, include design-intent (e.g., a design clip in OASIS format or any of the other types of design information described herein), imaging setup (e.g., pixel size, beam properties, etc.), and tool properties (e.g., a pre-calibrated tool/imaging model/NN). At runtime, the model takes imaging properties (e.g., resolution, layer interaction, etc.) into account and applies the model to the design. The output generated by the model (i.e., the rendered images) includes modeled images of the design-intent (how the image would look in a perfect world without process variation, tool noise, etc.). The computer subsystem may also modify the one or more characteristics (e.g., size) of the patterned features of interest in the design. For each imaging condition and each patterned feature characteristic, the computer subsystem may generated a rendered image from the (modified) design clip.

As described above, therefore, the computer subsystem may generate the rendered images. In addition, the computer subsystem may perform other steps described herein. Therefore, one computer subsystem may be configured for performing all of the steps described herein. However, any of the step(s) described herein may be distributed across as many different computer subsystem(s) as might be normally done to, for example, increase throughput or for practical considerations. For example, one computer subsystem may generate the rendered images as described herein, and another computer subsystem may perform other steps described herein. In addition, the computer subsystem(s) that perform any of the steps described herein may be coupled to an imaging subsystem or part of the system that includes the imaging subsystem. In this manner, the steps described herein may be performed on-tool, and some or all of the steps may be performed during runtime of a metrology process performed on the specimen by the system.

The computer subsystem is configured for comparing the image(s) of the specimen generated by the imaging subsystem to rendered images generated for the mode(s) and at least one instance of a design for the specimen corresponding to at least one of different values of at least one characteristic of patterned feature(s) in the design. In this manner, the computer subsystem may compare each of the measured image(s) to the rendered images at the location of the patterned features of interest. For example, as shown in FIG. 3, measured image(s) 300 may be compared to each of rendered images 302. In other words, each measured image may be compared to each rendered image. In this manner, a measured image generated with one mode may be compared to the rendered images for each of the mode(s) and each of the patterned feature characteristic value(s). However, as an alternative, each measured image may be compared to only the rendered images for the mode used to measure the image. For example, an image measured with Mode 1 may only be compared to rendered images for Mode 1, an image measured with Mode 2 may only be compared to rendered images for Mode 2, and so on. In any case, the comparing step may generate results 304 that include comparison results per mode and CD value (in the case of a CD patterned feature characteristic).

The computer subsystem is also configured for determining one or more quality merits for results of the comparing, as shown in step 306. In this manner, the computer subsystem may extract one or multiple quality merits from the results of the comparing step. In general, the quality merit(s) that are determined by the computer subsystem may be any suitable quality merit(s) and may vary depending on the comparison method used. In some embodiments, the one or more quality merits are responsive to a correlation between each of the one or more images of the specimen generated by the imaging subsystem and the rendered images. In other words, the quality merits may be based on a correlation of the measured image to each of the rendered images. For example, the quality merits may include similarity between measured and rendered images for normalized cross-correlation (NCC) and root-mean-square error (RMSE) methods. Other merits include differences of optimization results from different imaging conditions. Another suitable merit takes the curvatures of the optimization landscapes close to the optimum into account. More generally though, any quantitative or qualitative methods of expressing the similarity of two images being compared to each other as described herein may be used as the quality merit(s) in the embodiments described herein.

The computer subsystem is further configured for optimizing the one or more quality merits using an optimization method, as shown in step 308. In this manner, the computer subsystem may optimize one or multiple quality merits using a search or optimization algorithm or method. In general, any search or optimization algorithm or method may be used in the embodiments described herein and may be selected based on the comparison results and the comparisons that are performed. Some non-limiting examples of search or optimization algorithms that may be used in the embodiments described herein include, but are not limited to, the gradient descent algorithm, a multi-objective genetic algorithm, particle swarm optimization, simulated annealing, and any such algorithm combined with methods like surrogate optimization. All of these algorithms may have any suitable configuration known in the art.

In one embodiment, the one or more modes include multiple modes, and the comparing includes comparing the one or more images of the specimen generated by the imaging subsystem with the multiple modes to the rendered images generated for all of the multiple modes. For example, in the case of multiple imaging conditions (modes), the quality merit(s) in the full search space across all imaging conditions can be optimized. In other words, the optimization step described above may be performed to try to find a “solution” that fits best to all imaging modes at once. In such cases, the computer subsystem may try to achieve this objective using a multi-objective optimization algorithm or defining a cost function which weights the individual contributing imaging conditions correctly. The actual design of the objectives and/or weights may vary depending on the exact “shape” of the optimization landscape.

Using multiple mode rendered and measured images in this manner can improve the results particularly in case of nearly identical pattern signals that can only be separated by taking the different imaging properties of the imaging modes into account. In addition, taking the imaging properties into account and using multiple imaging conditions can advantageously enable substantially accurate separation of signals from individual layers. As such, even relatively low-resolution imaging conditions (e.g., faster measurements, through-stack measurements, etc.) can be used to accurately report CDs (pattern sizes) and other patterned feature characteristics described herein.

In one embodiment, the optimizing includes sub-sampling in a solution space defined by the one or more modes and the at least one instance of the design. For example, the embodiments described herein may optimize the overall correlation of the simulated images to the measured images across all imaging conditions at once. In addition, the computer subsystem may be configured for interpolating results between two sampling points (rendered images) to generate sub-sampled results. One example configuration that enables sub-sampling is a surrogate optimization, which uses approximated, smooth functions in the area of expected global minimum/maximum. These functions can be easily optimized between existing sampling points. In general, a multi-objective optimization of multiple merits with sub-sampling/sub-resolution may be used.

In another embodiment, the optimizing includes identifying, based on the one or more quality merits, a new sample point defined by an additional mode of the imaging subsystem or an additional instance of the design corresponding to an additional value of the at least one characteristic, generating an additional rendered image for the new sample point, repeating the comparing for the additional rendered image, determining the one or more quality merits for results of the repeated comparing, and optimizing the one or more quality merits determined for the results of the comparing and results of the repeated comparing using the optimization method. In this manner, the computer subsystem may be configured for generating new sample points on-the-fly. The optimizing may be performed using all of the comparison results generated for both the original and any new sample points. The new sample point may be identified in any suitable manner, i.e., as a sample point between a local maximum/minimum sample point and the next closest sample point. The rendered and measured images at the new sample point may be generated and compared as described herein. Additional steps described above may be performed for the repeated comparing step as described herein. The computer subsystem may also generate more than one new sample point and the steps described above may be performed for each new sample point. For example, the steps described herein may be performed for new sample points until the quality merit(s) are optimized.

The computer subsystem is configured for determining one or more characteristics of the one or more patterned features on the specimen from results of the optimizing. The results of this step may then include CD results 310. In this manner, an imaging subsystem may acquire one or more images of one or more patterned features on a specimen. From such image(s) and results of comparing the image(s) to rendered images generated by inputting design and imaging subsystem (mode) information into a pre-calibrated model of the imaging subsystem, the computer subsystem can extract characteristic(s) such as CD of individual patterned features of interest by determining and optimizing the one or more quality merits as described herein. For example, the CD results may be the CD of the rendered image that has the best quality merit(s) for a measured image.

In one embodiment, the determined one or more characteristics include a CD of the one or more patterned features. In particular, the embodiments described herein have been primarily created for the purpose of determining or measuring CD of patterned features on wafers, reticles, etc. The CD that the embodiments are used for may vary depending on the patterns of interest and their relevant CD(s). In addition, as described further herein, the characteristics may be determined for upper surface patterned features or buried layer patterned features. For example, the CDs may be a top CD, i.e., a CD of a patterned feature at or proximate to the upper surface of the specimen. In addition or alternatively, the CDs may be bottom CDs, i.e., a CD of a patterned feature at or near the bottom of the patterned feature. The CDs may also include CDs of patterned features that are formed under one or more materials since the embodiments can be used with imaging parameters that allow features below the upper surface and/or covered by one or more materials to be measured.

The embodiments described herein are also not so limited. For example, in addition to or instead of CD, the embodiments may be used for measuring or determining other patterned feature characteristics such as contour, other shape characteristics, side wall angle (SWA) or the angle of the side of the specimen relative to nominal, roughness including line edge roughness (LER), etc. In addition to such patterned feature characteristics, the embodiments may be used for measuring overlay of the patterned features on one layer vs. another layer.

Depending on which patterned feature characteristics are of interest, the patterned features themselves, materials formed on the specimen, etc., the parameters of the imaging subsystems described herein used to generate the measured images may vary. For example, imaging subsystem parameters suitable for measuring patterned feature characteristics at the upper surface of the specimen may not also be suitable for measuring patterned feature characteristics below the upper surface. The computer subsystem or another system or method may be configured for selecting the imaging subsystem parameters based on the patterned feature characteristics of interest as described further herein or in any other suitable manner known in the art. Once the imaging subsystem parameters have been selected, the imaging subsystem model may be updated with those parameters and rendered images may be generated as described herein for different values of the patterned feature characteristics. Those rendered images may then be used as described herein to determine the patterned feature characteristic(s).

As described further herein, the comparing step is performed for one or more modes of the imaging subsystem and at least one instance of the design corresponding to at least one of different patterned feature characteristic values. The results of the comparing step are then used to determine and optimize the quality merit(s) across imaging subsystem mode and patterned feature characteristic value(s). Performing these steps as a function of imaging subsystem mode and patterned feature characteristic value(s) is believed to be a new approach for metrology and provides significant advantages for the embodiments described herein. For example, one new feature of the embodiments described herein is using a combination of modeling of imaging conditions (modes) to improve accuracy of the results and modifying design parameters to extract the CD (pattern size) and/or other characteristics of individual patterns of interest. An additional important new feature of the embodiments described herein is that they can take multiple imaging conditions into account to accurately separate signals from individual layers that are hard/impossible to separate using a single imaging condition.

In another embodiment, the determined one or more characteristics include a characteristic of the patterned features below an upper surface of the specimen. For example, as described further herein, because the embodiments can be used with a wide range of imaging conditions (modes), the embodiments are capable of measuring patterned feature characteristics at the upper surface and buried layers. In addition, the embodiments described herein can be used with imaging conditions (modes) described further herein that make it possible to determine patterned feature characteristic(s) of buried layers and multiple layers at once (at the same time).

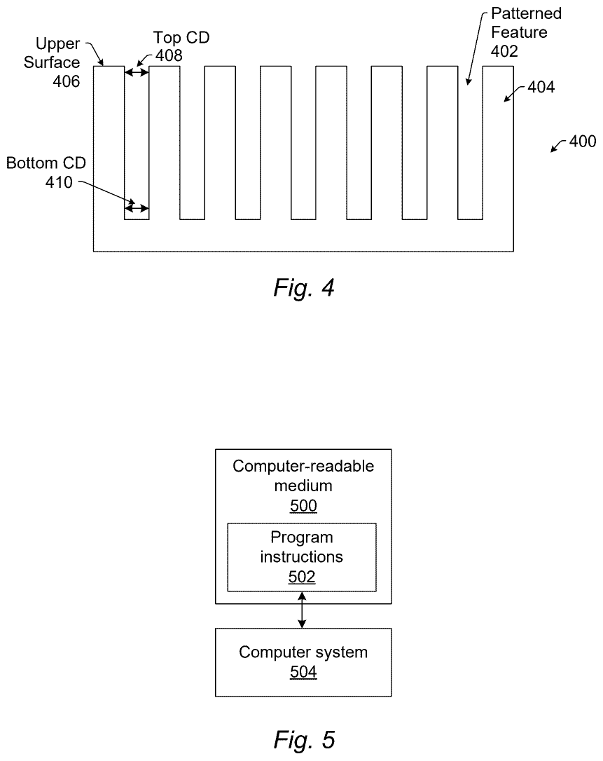

To illustrate such patterned feature characteristics, FIG. 4 shows a substantially simple illustration of some such patterned features having characteristics both at the upper surface and buried layers that may be of interest. Of course, the patterned features shown in FIG. 4 are not meant to illustrate any particular patterned features that may be formed on any of the specimens described herein. In this example, specimen 400 includes patterned features 402 formed in material(s) 404 (shown generically in FIG. 4 as a single material but can be made up of multiple (and possibly alternating) layers of different materials). The patterned features are shown in FIG. 4 as substantially deep trenches that might be found in some 3D NAND type devices and/or devices that include high aspect ratio (HAR) device structures. For such structures, the CDs of interest may include top CD 408 at or near upper surface 406 of material(s) 404 and bottom CD 410 at or near the bottom of the patterned features. The patterned features may be measured before or after being filled with one or more other materials (not shown).

In one such embodiment, generating the one or more images does not include altering the one or more patterned features or the specimen. For example, the embodiments described herein advantageously provide non-destructive, through-stack CD (and other patterned feature characteristic) extraction. Through-stack measurements are not available on standard CD SEMs today. In addition, unlike the embodiments described herein, transmission electron microscope (TEM) measurements are destructive. For these and other reasons described herein, the embodiments allow more than 10 times faster measurements compared to currently used methods on a standard CD SEM or TEM.

In one embodiment, the optimizing and determining the one or more characteristics steps are performed without the one or more images generated by the imaging subsystem. In another embodiment, the one or more images generated by the imaging subsystem are only used for the comparing step. For example, once the images are compared to the rendered images, they are not used for any other steps performed by the computer subsystem. In other words, the characteristic(s) of the patterned feature(s) are not determined directly from the measured images. Some currently used methods and systems may compare patterned feature characteristics determined from measured images to something else like reference patterned feature characteristics, e.g., to determine additional information about the specimen or the patterned feature characteristics. But in those cases, the comparisons are performed after the patterned feature characteristics are determined directly from the measured images. The embodiments described herein, however, perform no such direct image measurements, regardless of whether they are then used for comparisons or not.

The embodiments described herein, therefore, eliminate a substantial source of difficulty in other metrology methods and systems. In particular, there are often disadvantages and difficulties in generating specimen images that are suitable for use in determining patterned feature characteristic(s) directly from the images. More specifically, generating such images often takes a significantly longer amount of time compared to the throughput needed for inline measurements and can often require a destructive method that makes the measurements unsuitable for use in device production. In addition, determining patterned feature characteristic(s) directly from images that are generated faster and/or with lower resolution and without damaging the specimen generally requires fairly complex methods and algorithms whose capability for accurately determining patterned feature characteristic(s) is dependent on a number of variables including the images themselves. One such method does not use the image modeling approach described herein but applies deep learning (DL) or ML techniques to directly extract CDs and/or other patterned feature characteristic(s) from measured images. These methods, however, disadvantageously need a substantially large amount of substantially accurate external reference data for training the DL/ML algorithm.

In general, methods that determine patterned feature characteristics directly from images can have limited applicability to all of the patterned feature characteristics that may be of interest for some specimens described herein. For example, such methods and systems may have particular difficulty and limited accuracy for determining characteristics of densely packed patterned features and/or patterned features that are stacked on top of each other. Such patterned features may, however, be particularly important for some of the specimens described herein. The embodiments described herein can be used for such structures and any structures that can be fabricated on the specimens described herein (as long as suitable models exist and can be used to generate rendered images for such structures).

In one embodiment, the imaging subsystem is configured for generating the one or more images with electrons. Such an imaging subsystem may be configured as described further herein.

In one such embodiment, the generated one or more images are low resolution images. The term “low resolution images” as used herein is defined as images generated with one or more of the low-resolution imaging conditions described herein. For example, the images that can be used by the embodiments described herein for substantially accurately determining patterned feature characteristics such as those described herein may advantageously be generated with low-resolution imaging conditions (faster measurements, through-stack measurements, etc.). The low-resolution imaging conditions may also be defined by the landing energy and beam current conditions described further herein.

In another such embodiment, the one or more modes are at least partially defined by a high landing energy of the electrons. A “high landing energy” is defined herein as a landing energy greater than 800 eV. Some commercially available electron beam imaging subsystems that are suitable for the embodiments described herein may use high landing energies such as 2 keV to 30 keV or even as high as 70 keV. In an additional such embodiment, the one or more modes are at least partially defined by a high beam current of the electrons. A “high beam current” as that term is used herein is defined as a beam current greater than 500 pA. Some commercially available electron beam imaging subsystems that may be suitable for use in the embodiments described herein may use a high beam current in a range from about 5 nA to 100 nA. The embodiments described herein enable CD (and other) metrology on high beam current (high voltage) SEMs, where a “high voltage” may be generally defined as a voltage greater than 800 V. Such SEMs can use relatively high landing energies to measure buried layers and multiple layers at once. In addition, such SEMs can use relatively high beam currents for substantially fast measurements (surface layer and/or buried layer).

Being able to use images generated with such imaging parameters (modes) for determining patterned feature characteristic(s) as described herein is advantageous for a number of important reasons. For example, due to the speed and non-destructive nature of the measurements (compared to TEM in particular), more individual patterns of interest can be sampled at the same time. For the same reasons, more substrates can be sampled at the same time, and in-line process control is enabled, as the wafers are not destroyed by the measurements (as would be necessary for TEM measurements).

In a further embodiment, the comparing, determining the one or more quality merits, optimizing, and determining the one or more characteristics steps are performed on-the-fly during a metrology process performed on the specimen by the system. In addition, modifying the size of the patterned features of interest in the design, generating rendered images for each of the modified patterned features of interest, comparing the measured and rendered images, extracting the quality merit(s), and optimizing the quality merit(s) may be performed iteratively on-the-fly. In other words, in some embodiments, the computer subsystem is configured for selecting the at least one of the different values for the at least one instance of the design based on the one or more images, and this selecting is performed on-the-fly during a metrology process performed on the specimen by the system. In this manner, the computer subsystem may make an initial guess as to the value of the characteristic of interest of the patterned feature(s) of interest in the specimen image(s) and then rendered images can be generated with the initial guess.

Selecting the value(s) of the characteristic of the patterned features may be performed in a variety of different ways. In one example, the computer subsystem may determine one or more characteristics of patterned feature(s) directly from one or more specimen images using one of the methods described herein configured for such direct-image measurements, and the resulting determined characteristic(s) can be used to generate corresponding rendered images for one or more modes of the imaging subsystem. In other words, a method that determines a patterned feature CD value directly from a specimen image can be used to generate an initial CD value for the rendering. Even if the other method generates CD values that are not particularly accurate, they may generate CD values that are good enough for use as starting points for image rendering that can then be used by the embodiments described herein to determine more accurate CD values. In other examples, the computer subsystem may select the at least one patterned feature characteristic value for which rendered images are initially generated based on the design (e.g., the characteristic value if the patterned features were formed as intended), based on a default value for a process performed on the specimen and/or general knowledge such as the usual patterned feature characteristic values for a type of device being formed on the specimen, based on an arbitrary value selected on-the-fly, etc.

In another embodiment, selecting the at least one of the different values includes modifying a size of the one or more patterned feature in the design. This selecting may be performed, for example, when the CD is the characteristic of interest and/or when size of the patterned features is expected to have an effect on the specimen images. In the same manner described above, modifying the size of the patterned feature(s) may be performed based on the specimen image(s) or based, not on the specimen image(s) but, on some characteristic of the design, a default value for the devices being formed, an arbitrary value, etc. In one such example, if the specimen image(s) look dramatically different than expected, then a size of the patterned feature(s) may be modified to be dramatically different than in the design.

In some embodiments, the computer subsystem is configured for generating the rendered images for the one or more modes and the at least one instance of the design corresponding to the selected at least one of the different values on-the-fly during the metrology process. In this manner, during the metrology process, the computer subsystem may generate rendered images for any of the mode(s) and design characteristic value(s). This image rendering may otherwise be performed as described herein.

In an additional embodiment, selecting the at least one of the different values, generating the rendered images, comparing the one or more images, determining the one or more quality merits, optimizing the one or more quality merits, and determining the one or more characteristics are performed iteratively on-the-fly during the metrology process. In other words, all of the steps described herein may be performed iteratively on-the-fly until the one or more quality merits have been satisfactorily optimized, at which point the one or more characteristics would be determined. In this manner, after each of the steps described herein has been performed for an initial guess (or initial guesses) for the patterned feature characteristic of interest, the steps may be reperformed for other characteristic value(s) in the same manner until some stopping criteria has been met (e.g., when quality merits have been optimized to some predetermined criteria). The embodiments described herein can therefore provide significant advantages since they provide significant flexibility in the patterned feature characteristic values for which rendered images are generated and then used in other steps described herein and they are fast enough that different patterned feature characteristic values can be considered iteratively and on-the-fly.

In an alternative implementation, generating the rendered images can be done once upfront (pre-runtime) with predefined patterned feature characteristic values (predefined pattern sizes) to create a database of rendered images, which can then be used in the comparing step, results of which can then be used in the extracting, and optimizing steps to search for an optimum using the database. The embodiments may also be implemented with any such combination of on-the-fly and advance performance of the steps described herein.

The characteristics that are determined by the embodiments described herein can be used in the same manner as any other metrology measurements performed on specimens such as those described herein. For example, as described further below, the determined characteristics can be used to determine information for and/or monitor and control one or more fabrication processes performed on the specimen. In addition to such functions, the determined characteristics can be further processed to determine additional information about the specimen and/or the processes performed on it. For example, the results obtained by the computer subsystem can be further post-processed to improve matching to an external reference. One way to do this is by applying a model-based function to the data.

The computer subsystem may also be configured for generating results that include the determined characteristic(s) of the patterned feature(s) on the specimen, which may include any of the results or information described herein. The results of determining the characteristic(s) may be generated by the computer subsystem in any suitable manner. All of the embodiments described herein may be configured for storing results of one or more steps of the embodiments in a computer-readable storage medium. The results may include any of the results described herein and may be stored in any manner known in the art. The results that include the determined characteristic(s) may have any suitable form or format such as a standard file type. The storage medium may include any storage medium described herein or any other suitable storage medium known in the art.

After the results have been stored, the results can be accessed in the storage medium and used by any of the method or system embodiments described herein, formatted for display to a user, used by another software module, method, or system, etc. to perform one or more functions for the specimen or another specimen of the same type. In addition, the results may include any information for the specimen determined as described herein.

That information may be used by the computer subsystem or another system or method for performing additional functions for the specimen. Such functions include, but are not limited to, altering a process such as a fabrication process or step that was or will be performed on the specimen in a feedback or feedforward manner, etc. For example, the computer subsystem may be configured to determine one or more changes to a process that was performed on the specimen and/or a process that will be performed on the specimen based on the determined characteristic(s). The changes to the process may include any suitable changes to one or more parameters of the process. In one such example, the computer subsystem preferably determines those changes such that any determined characteristic(s) that are outside of an acceptable range of values are corrected on other specimens on which the revised process is performed, are corrected on the specimen in another process performed on the specimen, are compensated for in another process performed on the specimen, etc. The computer subsystem may determine such changes in any suitable manner known in the art.

Those changes can then be sent to a semiconductor fabrication system (not shown) or a storage medium (not shown) accessible to both the computer subsystem and the semiconductor fabrication system. The semiconductor fabrication system may or may not be part of the system embodiments described herein. For example, the imaging subsystem and/or the computer subsystem described herein may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a chemical-mechanical polishing (CMP) tool, a deposition tool, and the like.

Each of the embodiments of each of the systems described above may be combined together into one single embodiment.

Another embodiment relates to a computer-implemented method for determining one or more characteristics of one or more patterned features on a specimen. The method includes acquiring one or more images of a specimen generated with one or more modes of an imaging subsystem, respectively. The method also includes the comparing, determining one or more quality merits, optimizing, and determining one or more characteristics steps described above.

Each of the steps of the method may be performed as described further herein. The method may also include any other step(s) that can be performed by the imaging subsystem, computer subsystem, and/or system described herein. The steps of the method are performed by a computer subsystem, which may be configured according to any of the embodiments described herein. In addition, the method described above may be performed by any of the system embodiments described herein.

An additional embodiment relates to a non-transitory computer-readable medium storing program instructions executable on a computer system for performing a computer-implemented method for determining one or more characteristics of one or more patterned features on a specimen. One such embodiment is shown in FIG. 5. In particular, as shown in FIG. 5, non-transitory computer-readable medium 500 includes program instructions 502 executable on computer system 504. The computer-implemented method may include any step(s) of any method(s) described herein.

Program instructions 502 implementing methods such as those described herein may be stored on computer-readable medium 500. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), SSE (Streaming SIMID Extension) or other technologies or methodologies, as desired.

Computer system 504 may be configured according to any of the embodiments described herein.

Further modifications and alternative embodiments of various aspects of the invention will be apparent to those skilled in the art in view of this description. For example, methods and systems for determining one or more characteristics of one or more patterned features on a specimen are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A system configured for determining one or more characteristics of one or more patterned features on a specimen, comprising:
an imaging subsystem configured for generating one or more images of a specimen with one or more modes of the imaging subsystem, respectively; and
a computer subsystem configured for:
comparing the one or more images of the specimen generated by the imaging subsystem to rendered images generated for the one or more modes and at least one instance of a design for the specimen corresponding to at least one of different values of at least one characteristic of one or more patterned features in the design;
determining one or more quality merits for results of said comparing;
optimizing the one or more quality merits using an optimization method; and
determining one or more characteristics of the one or more patterned features on the specimen from results of the optimizing.

2. The system of claim 1, wherein said optimizing and said determining the one or more characteristics are performed without the one or more images generated by the imaging subsystem.

3. The system of claim 1, wherein the one or more images generated by the imaging subsystem are only used for the comparing step.

4. The system of claim 1, wherein the determined one or more characteristics comprise a critical dimension of the one or more patterned features.

5. The system of claim 1, wherein the determined one or more characteristics comprise a characteristic of the patterned features below an upper surface of the specimen.

6. The system of claim 5, wherein generating the one or more images does not comprise altering the one or more patterned features or the specimen.

7. The system of claim 1, wherein the computer subsystem is further configured for identifying responsivities of the modes of the imaging subsystem to the one or more characteristics and selecting at least two of the modes included in the one or more modes having different of the identified responsivities.

8. The system of claim 1, wherein the computer subsystem is further configured for identifying responsivities of the modes of the imaging subsystem to different layers formed on the specimen and selecting at least two of the modes included in the one or more modes having different of the identified responsivities.

9. The system of claim 1, further comprising one or more components executable by the computer subsystem, wherein the one or more components comprise a model of the imaging subsystem, and wherein the computer subsystem is further configured for generating the rendered images by inputting into the model information for the one or more modes and the at least one instance of the design.

10. The system of claim 1, wherein the one or more modes comprise multiple modes, and wherein said comparing comprises comparing the one or more images of the specimen generated by the imaging subsystem with the multiple modes to the rendered images generated for all of the multiple modes.

11. The system of claim 1, wherein the one or more quality merits are responsive to a correlation between each of the one or more images of the specimen generated by the imaging subsystem and the rendered images.

12. The system of claim 1, wherein said optimizing comprises sub-sampling in a solution space defined by the one or more modes and the at least one instance of the design.

13. The system of claim 1, wherein said optimizing comprises identifying, based on the one or more quality merits, a new sample point defined by an additional mode of the imaging subsystem or an additional instance of the design corresponding to an additional value of the at least one characteristic, generating an additional rendered image for the new sample point, repeating the comparing for the additional rendered image, determining the one or more quality merits for results of the repeated comparing, and optimizing the one or more quality merits determined for the results of said comparing and results of said repeated comparing using the optimization method.

14. The system of claim 1, wherein the imaging subsystem is further configured for generating the one or more images with electrons.

15. The system of claim 14, wherein the generated one or more images are low resolution images.

16. The system of claim 14, wherein the one or more modes are at least partially defined by a high landing energy of the electrons.

17. The system of claim 14, wherein the one or more modes are at least partially defined by a high beam current of the electrons.

18. The system of claim 1, wherein said comparing, said determining the one or more quality merits, said optimizing, and said determining the one or more characteristics are performed on-the-fly during a metrology process performed on the specimen by the system.

19. The system of claim 1, wherein the computer subsystem is further configured for selecting the at least one of the different values for the at least one instance of the design based on the one or more images, and wherein said selecting is performed on-the-fly during a metrology process performed on the specimen by the system.

20. The system of claim 19, wherein said selecting the at least one of the different values comprises modifying a size of the one or more patterned features in the design.

21. The system of claim 19, wherein the computer subsystem is further configured for generating the rendered images for the one or more modes and the at least one instance of the design corresponding to the selected at least one of the different values on-the-fly during the metrology process.

22. The system of claim 21, wherein said selecting the at least one of the different values, generating the rendered images, comparing the one or more images, determining the one or more quality merits, optimizing the one or more quality merits, and determining the one or more characteristics are performed iteratively on-the-fly during the metrology process.

23. A non-transitory computer-readable medium, storing program instructions executable on a computer system for performing a computer-implemented method for determining one or more characteristics of one or more patterned features on a specimen, wherein the computer-implemented method comprises:
acquiring one or more images of a specimen generated with one or more modes of an imaging subsystem, respectively;
comparing the one or more images of the specimen generated by the imaging subsystem to rendered images generated for the one or more modes and at least one instance of a design for the specimen corresponding to at least one of different values of at least one characteristic of one or more patterned features in the design;
determining one or more quality merits for results of said comparing;
optimizing the one or more quality merits using an optimization method; and
determining one or more characteristics of the one or more patterned features on the specimen from results of the optimizing.

24. A computer-implemented method for determining one or more characteristics of one or more patterned features on a specimen, comprising:
acquiring one or more images of a specimen generated with one or more modes of an imaging subsystem, respectively;
comparing the one or more images of the specimen generated by the imaging subsystem to rendered images generated for the one or more modes and at least one instance of a design for the specimen corresponding to at least one of different values of at least one characteristic of one or more patterned features in the design;
determining one or more quality merits for results of said comparing;
optimizing the one or more quality merits using an optimization method; and
determining one or more characteristics of the one or more patterned features on the specimen from results of the optimizing, wherein said acquiring, comparing, determining the one or more quality merits, optimizing, and determining the one or more characteristics are performed by a computer subsystem.
